(19) United States
(12) Patent Application Publication
(10) Pub. No.: US 2011/0079918 A1
(43) Pub. Date: Apr. 7, 2011

(54) PLASMA-BASED ORGANIC MASK REMOVAL WITH SILICON FLUORIDE

(75) Inventors: Yifeng ZHOU, Sunnyvale, CA (US); Qingjun Zhou, Sunnyvale, CA (US); Ling Wang, San Jose, CA (US); Nancy Fung, Livermore, CA (US); Jeremiah T. Pender, San Jose, CA (US)

(73) Assignee: Applied Materials, Inc., Santa Clara, CA (US)

(21) Appl. No.: 12/894,659

(22) Filed: Sep. 30, 2010

Related U.S. Application Data
(60) Provisional application No. 61/247,902, filed on Oct. 1, 2009.

(51) Int. Cl. H01L 23/522; H01L 21/768

(52) U.S. Cl. 257/774; 438/725; 257/E23.145; 257/E21.577

(57) ABSTRACT

Removal of organic mask material from an etched dielectric film with an etchant gas mixture including silicon fluoride (SiF₄). In certain embodiments, SiF₄ is combined in an etchant gas mixture of molecular nitrogen (N₂), carbon dioxide (CO₂) to in-situ strip an organic mask material from a porous low-k dielectric film that has been etched to form a damascene interconnect structure with reduced etch profile bowing and reduced ashing damage to the low-k dielectric film.

### CROSS-REFERENCE TO RELATED APPLICATIONS

This application is related to PROVISIONAL PATENT APPLICATION 61/247,902 filed Oct. 1, 2009, incorporated by reference in its entirety for all purposes.

### BACKGROUND

1. Field

Embodiments of the present invention relate to the electronics manufacturing industry and more particularly to the process of plasma etching, stripping or ashing of organic masks.

2. Discussion of Related Art

As the feature size of microelectronic devices gets smaller than 100 nm, the critical dimension (CD) requirement of features becomes a more important criterion for stable and repeatable device performance. Allowable CD variation across a substrate has also scaled with the scaling of feature CD. For example, across a 300 mm diameter substrate, some applications may demand a 3-sigma of less than 10 nm for a target CD averaging about 80 nm.

For back end of line (BEOL) etch processes, post-etch organic mask removal processes may enlarge the CD of etched openings (e.g., a via). As feature sizes are reduced, the proportion of dimensional change attributable to the post-etch organic mask removal process becomes an ever more significant limitation. One contributor to such dimensional change and/or “profile bowing” is a release of fluorocarbons as dielectric etch deposits (from fluorocarbon etchants employed in the dielectric etch) are removed by the post-etch mask removal process. Via profile bowing is particularly problematic with low-k (e.g., dielectric constants below about 3.0) and ultra-low-k (e.g., dielectric constants below about 2.5) materials because of their porous nature and mechanical fragility. Accelerated etch rates of such low-k/ultra low-k materials may lead to undercutting of a dielectric etch stack, which may prevent a via from being adequately filled with conductive material. The release of fluorocarbons during the post-etch plasma-based organic mask removal process may also deleteriously etch/undercut BEOL hard masks (e.g., non-carbonaceous masks), stop layers, or diffusion barriers exposed during the BEOL dielectric etch.

### SUMMARY

Embodiments of the present invention include plasma etching or stripping of organic mask materials, such as photo resist, with an etchant gas mixture including silicon fluoride. In certain embodiments, the etchant gas mixture comprises silicon fluoride and at least one other of: forming gas (H₂:N₂), molecular nitrogen (N₂), ammonia (NH₃), carbon monoxide (CO),carbon dioxide (CO₂), oxygen (O₂), sulfur dioxide (SO₂), water vapor (H₂O), ozone (O₃), hydrogen peroxide (H₂O₂), or carbonyl sulfide (COS).

In a first embodiment, a substrate including an etched dielectric film disposed under an organic mask is provided to a plasma etch chamber. With a fluorocarbon etch product disposed on one or more of the plasma etch chamber, organic mask, or etched dielectric film, the etched dielectric film and organic mask is exposed to a plasma of a first etchant gas including silicon tetrafluoride (SiF₄). The etched dielectric film and organic mask may be exposed to the plasma of the first etchant gas for a duration sufficient to remove at least a majority of the organic mask thickness remaining over the etched dielectric film. Addition of the SiF₄ to the first etchant gas may reduce the lateral etch of the etched dielectric features (e.g., profile bowing) and reduce the damage of low-k dielectrics caused by the plasma etching/ashing process. Addition of the SiF₄ to the first etchant gas may reduce over etch and/or undercut of exposed stop/barrier layers.

In a second embodiment, a plasma etch method is performed with a plasma etch chamber to form a feature (e.g., a via) in a first layer of a dielectric stack disposed under a first mask including a patterned photo resist layer. The feature may be etched with an etchant gas including a fluorocarbon species until a stop layer is exposed. The plasma etch method further includes removing the patterned photo resist layer with a plasma of a second etchant gas including silicon tetrafluoride (SiF₄), and unloading the plasma etch chamber. The plasma etch method may then be continued upon receiving the substrate with the dielectric stack disposed under a second mask including a non-patterned organic layer filling in the feature. A second plasma dielectric etch is performed to form a second feature (e.g., a trench) in the first layer of the dielectric stack with a third etchant gas. The non-patterned organic layer is then removed from the feature (e.g., the via) with a plasma of a fourth etchant gas including silicon tetrafluoride (SiF₄).

### BRIEF DESCRIPTION OF THE DRAWINGS

Embodiments of the invention are particularly pointed out and distinctly claimed in the concluding portion of the specification. Embodiments of the invention, however, both as to organization and method of operation, together with objects, features, and advantages thereof, may best be understood by reference to the following detailed description when read with the accompanying drawings.

FIG. 1A illustrates a cross sectional view of a via etched in a dielectric film disposed under an organic mask, in accordance with a particular embodiment.

FIG. 1B illustrates a cross sectional view of the via illustrated in FIG. 1A after the organic mask is removed, in accordance with one embodiment.

FIG. 2 is a flow chart of a method of etching a dielectric film disposed under an organic mask, in accordance with one embodiment.

FIG. 3 is schematic illustrating a cross-section view of a plasma etch apparatus configured to perform a method of etching a dielectric film underlying an organic mask, in accordance with an embodiment.

FIGS. 4A, 4B, 4C, 4D, 4E, 4F, 4G, 4H, 4I, 4J and 4K illustrate cross-sectional views of a damascene interconnect structure after particular operations in a via first damascene etch process, in accordance with a particular embodiment.

### DETAILED DESCRIPTION

In the following description, numerous specific details are set forth to provide a thorough understanding of the present invention. It will be apparent to one skilled in the art that the present invention may be practiced without these specific details. In other instances, well-known features, such as specific lithographic patterning and etching techniques, are not described in detail in order to not unnecessarily obscure the present invention. Reference throughout this specification to “an embodiment” means that a particular feature, structure, material, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, materials, or characteristics may be combined in any suitable manner in one or more embodiments. Also, it is to be understood that the various exemplary embodiments shown in the Figures are merely illustrative representations and are not necessarily drawn to scale.

The terms “over,” “under,” “between,” and “on” as used herein refer to a relative position of one layer with respect to other layers. As such, for example, one layer deposited or disposed over or under another layer may be directly in contact with the other layer or may have one or more intervening layers. Moreover, one layer deposited or disposed between layers may be directly in contact with the layers or may have one or more intervening layers. In contrast, a first layer “on” a second layer is in contact with that second layer. Additionally, the relative position of one layer with respect to other layers is provided assuming operations deposit, modify and remove films relative to a starting substrate without consideration of the absolute orientation of the substrate.

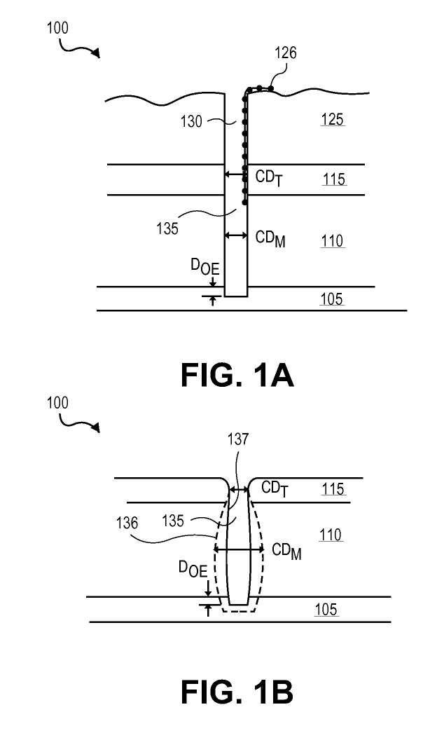

FIG. 1A illustrates a cross sectional view of a structure 100 including a via 135 etched in a dielectric film including a first dielectric layer 110 and a second dielectric layer 115 disposed under organic mask 125 patterned with an opening 130, in accordance with a particular embodiment. As illustrated, the via 135 is landed on a barrier or etch stop layer 105. Depending on the embodiment, the dielectric film may include fewer (e.g., 1) or more (e.g., 3, 4, 5, etc.) layers than illustrated in FIG. 1A. During the etch of the via 135, a fluorocarbon etch product 126 is deposited on a sidewall of the via 135 and/or a surface of the organic mask 125. As used herein, profile bowing of the via 135 may be characterized by a CD delta between a top CD, “CD_{T},” measured proximate the patterned mask opening 130 and a middle CD “CD_{M},” measured proximate to the middle depth of the via 135. In FIG. 1A, there is essentially no profile bowing present after etching the dielectric layers 110 and 115 such that CD_{M}−CD_{T} =0. Overetch of the stop layer 105 may also be characterized based the depth of the via 135, “D_{OE,} ” extending into the stop layer 105.

FIG. 1B illustrates a cross sectional view of the via 135 after the organic mask 125 is removed from the top surface of the etch dielectric film (e.g., top surface of the dielectric layer 115). The fluorocarbon etch product 126 has also been substantially removed and a small amount of profile bowing (solid line via profile 137) has occurred as a result of the organic mask removal process such that CD_{M}−CD_{T} >0. The amount of profile bowing attributable to the mask removal is therefore referred to herein as a “bowing delta.” Similarly, the organic mask removal process may also increase the overetch depth D_{OE} in the stop layer 105 to be greater than it was prior to removal of the organic mask 125, resulting in an overetch delta between pre-post mask removal.

Depending on the material composition of the etched dielectric film and the nature of the mask removal process, the bowing delta may be more or less severe. For example, the dielectric layer 115 may be a silica hardmask having a first composition while the dielectric layer 110 may be an ultra low-k material such as a porous organosilicate. For such a structure, the dielectric layer 110 may be susceptible to significantly more lateral etching during the mask removal process than is the dielectric layer 115, increasing the bowing delta for a given mask removal process. Ultra low-k materials in particular are susceptible to incurring a damage layer when exposed to plasma conditions conventionally used for removing organic masks. The damage layer is generally attributed to a loss of terminating groups, leaving the damage layer susceptible to forming silanols.

In accordance with embodiments described herein, the profile bowing delta for dielectric films containing silicon is significantly reduced through the introduction of silicon fluoride, or more specifically silicon tetrafluoride (SiF₄), to the etchant gas during a plasma-based organic mask removal process. As further described herein, the over etch delta for stop layers including silicon is significantly reduced through the introduction of silicon fluoride, or more specifically silicon tetrafluoride (SiF₄), to the etchant gas during a plasma-based organic mask removal process. In a particular embodiment, for example, a plasma-based organic mask removal process without SiF₄ resulted in a profile bowing delta of about 18 nm for a particular dielectric material (dashed line via profile 136 in FIG. 1B). That same plasma-based organic mask removal process with the addition of SiF₄ resulted in a profile bowing delta of only about 5 nm for the same particular dielectric material (solid line via profile 137 in FIG. 1B). Given a post-etch profile bow (e.g., as depicted in FIG. 1A) may be typically on the order of a few nm, the addition of SiF₄ to the mask removal process may reduce the profile bowing delta from approximately 90% of the final profile bow (i.e., organic mask removal induced profile bow being many times greater than the via etch induced profile bow) to less than 50% of the final profile bow (i.e., organic mask removal induced profile bow being less than or equal to the via etch induced profile bow). As such, where CD values of the patterned mask openings 130 are on the order of 45 nm, the maximum CD of the via 135 may be reduced from approximately 60 nm to under 50 nm through the introduction of SiF₄ as described herein.

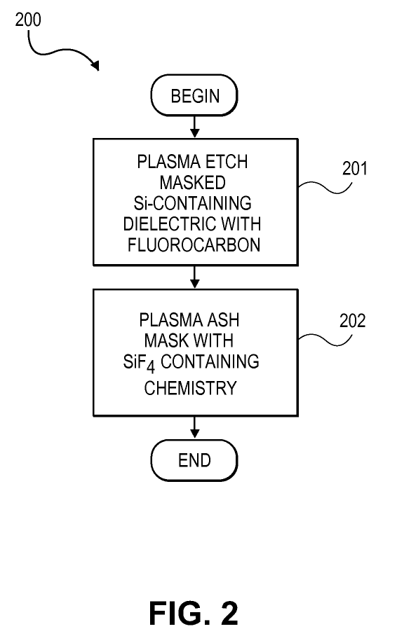

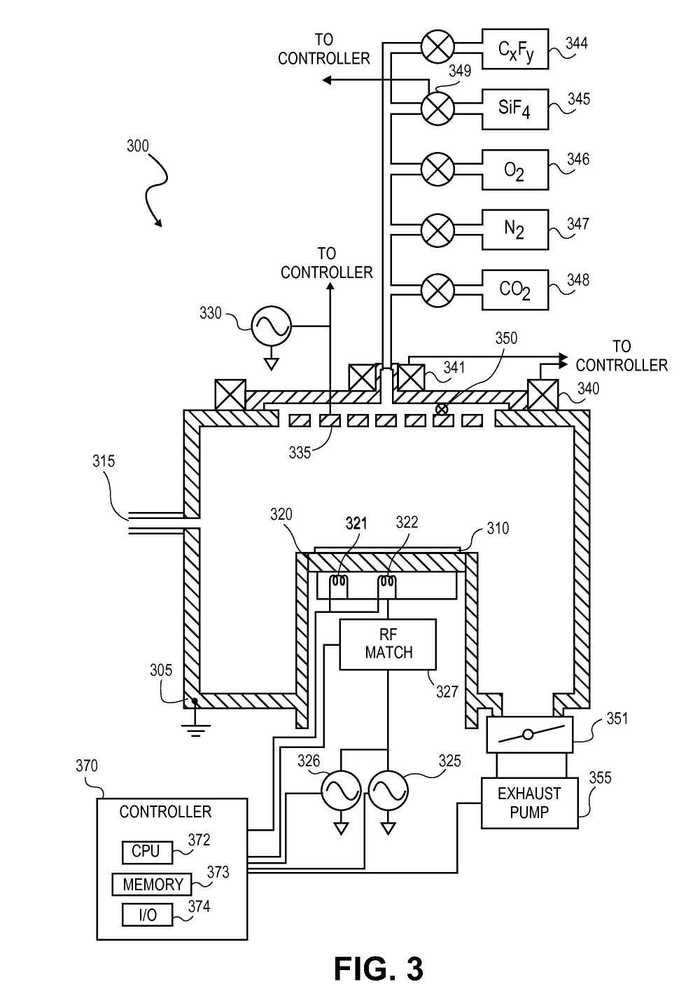

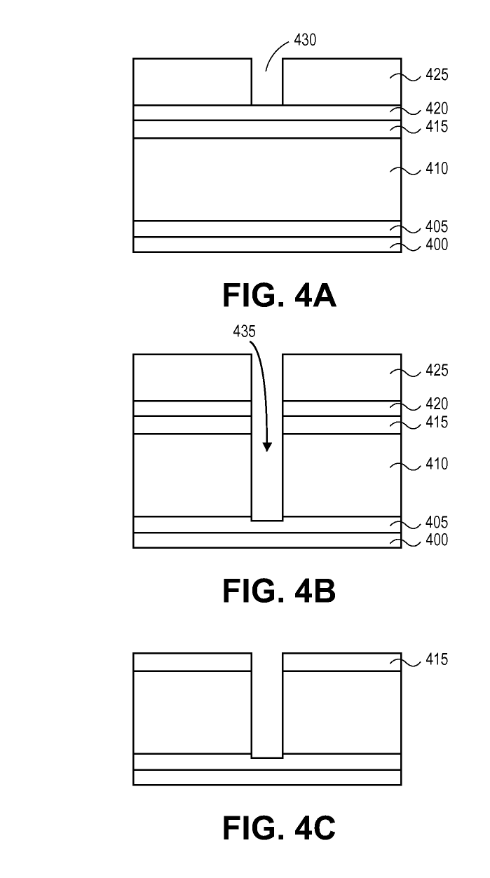

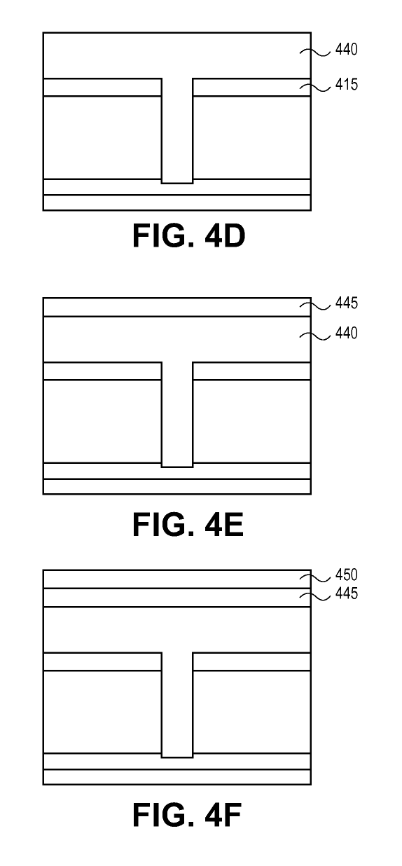

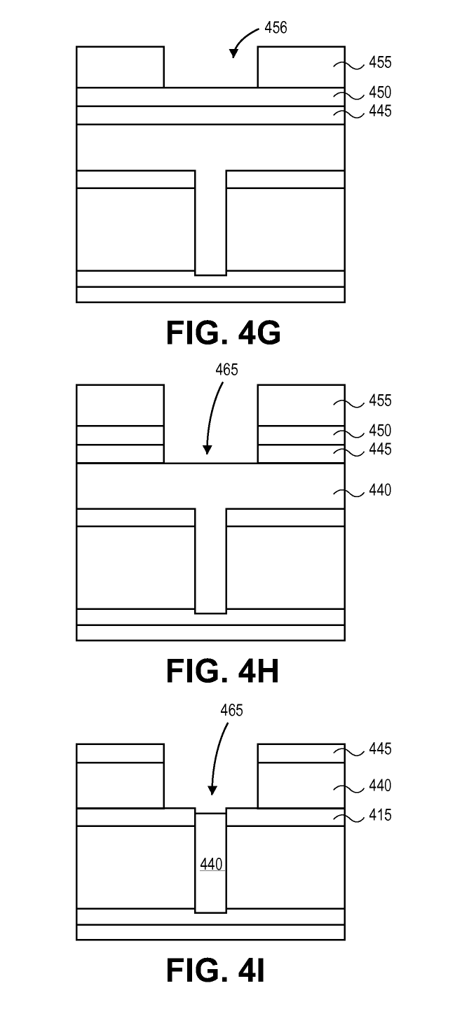

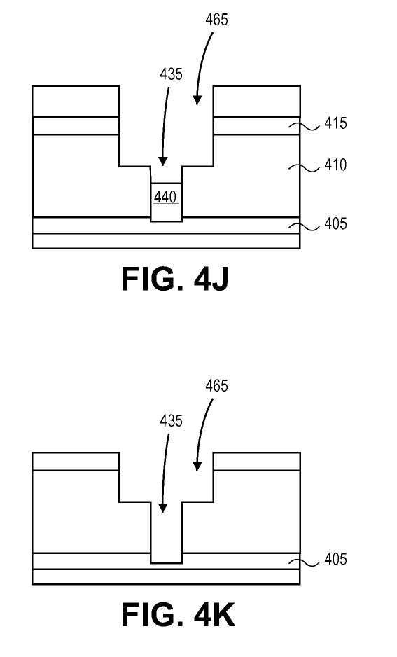

FIG. 2 illustrates a flow chart of a method 200 for etching a feature in accordance with one embodiment of the present invention. Method 200 may be performed on a substrate with a plasma etch system, such as that depicted in FIG. 3, during a fabrication process. FIGS. 4A-4K illustrate cross-sectional views of an exemplary substrate having a damascene interconnect feature fabricated in accordance with a particular implementation of the method 200.

At operation 201, a masked silicon-containing dielectric film is plasma etched with an etchant gas including a fluorocarbon source gas. In the exemplary embodiment depicted in FIG. 4A, the silicon-containing dielectric film may be part of a multi-layered dielectric stack disposed over a substrate 400. Generally, the substrate 400 may be any substrate conventionally employed in the fields of microelectronic, nanotechnology, photovoltaics, or the like. As one exemplary embodiment, substrate 400 is a semiconductor wafer, such as, but not limited to silicon, germanium, or a commonly known III-V compound semiconductor material. As another embodiment, substrate 400 is a glass (amorphous) material or sapphire.

The silicon-containing dielectric film may generally be any known in the art, such as, but not limited to, silicon nitride, silicon oxynitride, silicon dioxide (silica), and organosilicates (HSQ, MSQ, etc.). In certain embodiments, the silicon-containing dielectric film further includes oxygen and may be a low-k or ultra low-k material. In further embodiments, the silicon-containing dielectric film includes oxygen and carbon, such as a carbon-doped silicon oxide. In the exemplary embodiment depicted in FIG. 4A, the silicon-containing dielectric film is an ultra low-k layer 410 with a dielectric constant below approximately 2.5, such as SiCOH. The silicon-containing dielectric film may be disposed on an etch stop layer 405 comprising a material known to have good selectivity to the fluorocarbon-based process employed for etching the silicon-containing dielectric film, such as, but not limited to, silicon nitride and carbon-doped silicon nitrides. As one exemplary embodiment a SiCOH ultra low-k layer 410 is disposed on a silicon carbon nitride (SiCN) etch stop layer 405.

As further depicted in FIG. 4A, the ultra low-k layer 410 may be capped by one or more additional dielectric layer, such as hard mask layer 415, which has a composition or other structural properties which differ from those of the ultra low-k layer 410. Similarly, additional dielectric underlayers (not depicted) may also be disposed between the ultra low-k layer 410 and the stop layer 405. The hard mask layer 415 may be of any material commonly employed in the art, such as any of the silicon-containing dielectric films, the materials described for the stop layer 405, or the like. In an exemplary embodiment employing a ultra low-k layer 410, the hard mask layer 415 is silicon dioxide.

Over the silicon-containing dielectric film(s) is disposed an organic mask which may also include a plurality of layers of differing composition. In the exemplary embodiment depicted in FIG. 4A, the organic mask includes a patterned photo resist layer 425 disposed over an organic bottom anti-reflective coating (BARC) 420. The patterned photo resist layer 425 may be of any composition known in the art and is patterned to have an opening 430. In a particular embodiment, the opening 430 is a via having a CD between approximately 35 and 45 nm. The BARC 420 may be of any conventional composition, such as polyamides and polysulfones with less than 5 wt % carbon, but may also include materials having total carbon content less than about 20 wt %. In some embodiments, the organic mask layer may further include amorphous inorganic carbon layers (e.g., CVD carbon, DLC, etc.)

Returning to FIG. 2, at operation 201, the silicon-containing dielectric is etched with a fluorocarbon-based etch chemistry. As further depicted in FIG. 4B, each of the BARC 420, hard mask layer 415, and ultra low-k layer 410 are etched with one or more mixtures including at least one fluorocarbon-based etchant, such as, but not limited to CF₄ ,CHF₃,C2F6, C4F8, etc, to form, for example, a via 435. The duration of operation 201 is dependent on the thickness of the layers being etched (e.g., the BARC 420, hard mask layer 415, and ultra low-k layer 410).

Following the dielectric etch operation 201, the fluorocarbon-based chemistries employed may be purged from the etch process chamber. For example, a high volumetric flow of an inert, such as Argon, is introduced to the etch chamber to purge any halogen-based gas from the etch chamber before proceeding to operation 202 where the organic mask is removed to prevent carryover of residual halogens into subsequent processes performed in the etch chamber. Nonetheless, even with such a gas purge, fluorocarbon etch products will remain deposited on one or more of the organic mask surfaces (e.g., on the top surface and sidewall of photo resist layer 425), dielectric sidewalls (e.g., on the etched SiCOH sidewalls of via 335), or surfaces of the etch chamber (e.g., 305 in FIG. 3).

At operation 202, the organic mask is plasma etched (ashed) in an environment including SiF₄. In an embodiment, operation 202 is performed in-situ within the same etch chamber which performs operation 202 and may be performed for a duration sufficient to remove at least a majority of the organic mask thickness remaining over the etched dielectric film after operation 201.

It has been found that both the etched dielectric (e.g., via sidewalls) and etch stop layer/barrier layer film surface etch rate during the organic mask removal process may be reduced by introducing SiF₄ to the mask etchant chemistry. While not bound by theory, it is thought that reactant species such as fluorocarbon radicals resulting from fluorocarbon polymer etch deposits remaining after the operation 201, diffuse, and adsorb onto the exposed dielectric and etch stop /barrier layers. These reactant species are then energized (e.g., by ion bombardment) and react with the dielectric and stop/barrier layers to form etch products, such as SiF₂, SiF₃, and SiF₄, which can then desorb from the surface of the dielectric and stop/barrier layers. Addition of SiF₄ to the mask removal etchant chemistry is thought to increase the amount of such Si-containing etch products on the silicon-containing dielectric and/or etch stop/barrier layer surfaces to the point of saturation, reduce desorption of etch products, and reduce the removal of silicon from the silicon-containing dielectric and/or etch stop/barrier layers.

The SiF₄ etchant source gas may be provided as an additive to, or in combination with, essentially any conventional organic mask etchant gas to provide the silicon-containing etch product species. In an embodiment, etchant gas comprising SiF₄ is substantially free of any fluorocarbon source gases, such as any of those utilized in operation 201 (e.g., the fluorocarbon source gas used to etch the via 435 is discontinued before the introduction of the SiF₄, or shortly thereafter). SiF₄ may be combined with any of: O₂, CO₂, CO, COS, N₂, SO₂, H₂O, 0₃, forming gas (N₂:H₂) or NH₃ to form the organic mask etchant gas. Generally, higher partial pressures of SiF₄ reduce both the profile bowing delta and stop/barrier layer loss as well as the organic mask removal rate. Total gas flow of the etchant gas mixture including SiF₄ may vary widely, but will typically be relatively large (e.g., 300 to 1000 sccms or more) to maximize the organic mask removal rate. As one exemplary embodiment, at operation 202, the SiF₄ is introduced into a plasma etch chamber at a volumetric flow rate of up to about 50% of the total volumetric flow of the first etchant gas. In one particular embodiment, at operation 202, the SiF₄ is combined with CO₂, N₂ and provided into the plasma etch chamber at a CO₂:SiF₄ volumetric flow rate ratio of between about 2:1 and 10:1 and a total flow between 300 and 1000 sccm. Many other ratios and mixtures are of course readily achievable based on the embodiments described herein.

The positive effects of SiF₄ on the via profile has been found across a wide range of process pressures and plasma powers. When energized with a high frequency RF (above about 100 MHz) source powers of 500-2000 W (for a chamber accommodating a 300 mm substrate) the organic mask may be removed at reasonably high rates. Generally, bias power for the organic mask etch operation 202 should be significantly lower than the source power, typically on the order of below 100 W (300 mm system). Depending on the embodiment, the process pressure may be varied over a wide range between about 8 mT and 50 mT with a preferred process pressure of approximately 10 mT when energized with a high frequency capacitive system, as described elsewhere herein in reference to FIG. 3.

Returning to FIG. 4C, following operation 202, the organic mask (e.g., the patterned photo resist layer 425 and the BARC 420) has been substantially removed. Upon removing the substrate from the etch chamber, a wet clean, such as a hydrofluoric acid (HF) clean, may be performed (not depicted). Notably, contrary to the conventional plasma mask removal operations in which HF cleans result in a lateral loss of approximately 2-4 nm of low-k/ultra low-k dielectric along the via profile (through preferential etching of the low-k damage layer), it has been found that little to no additional low-k/ultra low-k dielectric loss occurs when an HF clean is performed subsequent to a plasma mask removal operation employing SiF₄ in accordance with embodiments describe herein. For example, a removal process with a 1:8:8 SiF4:CO2:N2 volumetric flow rate ratio was found to reduce the via profile bowing delta from 18 nm to 2 nm and reduce low-k damage from 3 nm/side to 0 nm/side. As such, it is thought the saturation of the SiF₄ etch products provide a passivation layer protecting the underlying low-k/ultra low-k dielectric from deleterious effects of the other species present in the organic mask removal operation (e.g., oxidizing radicals, etc.). Thus, in an embodiment, fluorocarbon etch products present after the dielectric etch operation 201 are removed and silicon fluoride etch products are deposited during the organic mask removal operation 202. Embodiments described herein may therefore mitigate ash damage to the low-k dielectric and minimize or eliminate the need for subsequent low-k dielectric repair treatments.

It has also been found that by increasing the SiF₄ partial pressure to a sufficient level during the removal operation 202, the overetch delta of the etch stop layer 405 may be significantly reduced. For example, a removal process with a 1:4:4 SiF₄:CO₂:N₂ volumetric flow rate ratio was found to further reduce the overetch delta of a SiCN etch stop layer 405 from approximately 21 nm to approximately 11 nm.

Proceeding with the exemplary embodiment illustrated in FIG. 4D, a second organic mask is formed over the etched silicon-containing dielectric layer (e.g., SiCOH layer 410 and hard mask layer 415). In the depicted embodiment, the second organic mask includes an organic BARC 440. BARC 440 may be of any of the materials previously described for BARC 420. Next, as illustrated in FIG. 4E, an inorganic cap layer 445, such as silicon oxide (LTO), SiON, or the like, is formed over the BARC 440. Referring to FIG. 4F, in preparation for a photo resist, a BARC 450 is deposited over the inorganic cap layer 445. The BARC 450 may again be of any of the materials previously described for BARC 420. A second patterned photo resist layer 455 is then formed as depicted in FIG. 4G. The patterned photo resist layer 455 includes an opening 456 which is aligned to the via 435 and has a larger CD than the via 435.

With the second organic mask complete, the substrate may again be placed in a plasma etch chamber to etch the masked silicon-containing dielectric a second time. In the exemplary embodiment, method 200 is repeated a second time with operation 201 opening the BARC 450 and the inorganic cap layer 445 (FIG. 4H), etching the BARC 440 (FIG. 41), and etching a trench into the silicon-containing dielectric (FIG. 4J) using conventional fluorocarbon-based plasma etch processes.

At operation 202, the remainder of the second organic mask is then removed with a plasma etch process including SiF₄, as depicted in FIG. 4K. Any of the plasma-based organic mask removal parameters described elsewhere herein for operation 202 may be applied to remove the second organic mask in substantially the same manner to substantially the same effect. For example, a SiF4:CO2:N2 plasma may be utilized in-situ within the dielectric etch chamber to remove the organic BARC 440 from the via 365, again with one or more of a significantly reduced profile bowing delta, significantly reduced over etch delta, or significantly reduced low-k dielectric damage. Following the mask removal operation 202, the stop layer 405 may then be removed (in the plasma etch system or otherwise) and/or a subsequent HF clean may be performed in preparation for filling the damascene structure with a conductor.

Embodiments of the organic mask removal methods described herein may be performed with a plasma etch apparatus, such as the EnablerTM etch chamber manufactured by Applied Materials, Inc. of CA, USA. In another embodiment, all the plasma etch processes of method 200 are performed in the EnablerTM etch chamber or a magnetically enhanced reactive ion etcher (MERIE) etch chamber, such as the MxP®, MxP+TM, Super-ETM or E-MAX® chamber also manufactured by Applied Materials, Inc. of CA, USA. Other types of high performance etch chambers known in the art may also be used, for example, chambers in which a plasma is formed using inductive techniques.

A cross-sectional view of an exemplary etch system 300 is shown in FIG. 3. System 300 includes a grounded chamber 305. A substrate 310 is loaded through an opening 315 and clamped to a temperature controlled cathode 320. In particular embodiments, temperature controlled cathode 320 include a plurality of zones, each zone independently controllable to a temperature setpoint, such as with a first thermal zone 322 proximate a center of substrate 310 and a second thermal zone 321 proximate to a periphery of substrate 310. Process gases, are supplied from gas sources 344, 345, 346, 347 and 348 through respective mass flow controllers 349 to the interior of the chamber 305. In certain embodiments, a NSTU 350 provides for a controllable inner to outer diameter gas flow ratio whereby process gases, such as a SiF₄/CO₂/N₂ etchant gas mixture, may be provided at a higher flow rate proximate to a center of substrate 310 or proximate a periphery of substrate 310 for tuning of the neutral species concentration across the diameter of substrate 310. Chamber 305 is evacuated to between 5 mTorr and 500 mTorr via an exhaust valve 351 connected to a high capacity vacuum pump stack 355 including a turbo molecular pump.

When RF power is applied, a plasma is formed in chamber processing region over substrate 310. Bias power RF generator 325 is coupled to cathode 320. Bias power RF generator 325 provides bias power to further energize the plasma. Bias power RF generator 325 typically has a low frequency between about 2 MHz to 60 MHz, and in a particular embodiment, is in the 13.56 MHz band. In certain embodiments, the plasma etch system 300 includes a third bias power RF generator 326 at a frequency at about the 2 MHz band which is connected to the same RF match 327 as bias power RF generator 325. Source power RF generator 330 is coupled through a match (not depicted) to a plasma generating element 335 which may be anodic relative to cathode 320 to provide high frequency source power to energize the plasma. Source RF generator 330 typically has a higher frequency than the bias RF generator 325, such as between 100 and 180 MHz, and in a particular embodiment, is in the 162 MHz band. Bias power affects the bias voltage on substrate 310, controlling ion bombardment of the substrate 310, while source power affects the plasma density relatively independently of the bias on substrate 310. It is noted that the etch performance of a given set of input gases from which the plasma is generated varies significantly with a plasma density and wafer bias, thus both the amount and frequency of power energizing the plasma are important. Because substrate diameters have progressed over time, from 150 mm, 200 mm, 300 mm, etc., it is common in the art to normalize the source and bias power of a plasma etch system to the substrate area.

In particular embodiments, the plasma etch chamber includes a CSTU for a controlling inner and out diameter magnetic field strength ratio to control the density of charged species in the plasma across the diameter of the substrate 310. One exemplary CSTU includes the magnetic coil 340 proximate a periphery of the substrate 310 and the magnetic coil 341 proximate a center of the substrate 310 to provide a magnetic field of between 0 G and about 25 G in either or both of an inner zone and outer zone of the chamber 305.

In an embodiment of the present invention, system 300 is computer controlled by controller 370 to control the low frequency bias power, high frequency source power, CSTU inner to outer magnetic field ratio, etchant gas flows and NSTU inner to outer flow ratios, process pressure and cathode temperatures, as well as other process parameters. Controller 370 may be one of any form of general-purpose data processing system that can be used in an industrial setting for controlling the various subprocessors and subcontrollers. Generally, controller 370 includes a central processing unit (CPU) 372 in communication with memory 373 and input/output (I/O) circuitry 374, among other common components. Software commands executed by CPU 372, cause system 300 to, for example, load the substrate into a plasma etch chamber, introduce an etchant gas mixture including SiF₄ into the plasma etch chamber and etch an organic mask with a plasma of the etchant gas mixture. Other processes, such as etching a mask silicon-containing dielectric layer, in accordance with the present invention, may also be executed by the controller 370.

Portions of the present invention may be provided as a computer program product, which may include a computer-readable medium having stored thereon instructions, which may be used to program a computer (or other electronic devices) to load a substrate into a plasma etch chamber, introduce an etchant gas mixture including SiF₄ into the plasma etch chamber and etch an organic mask with a plasma of the etchant gas mixture, in accordance with the present invention. The computer-readable medium may include, but is not limited to, floppy diskettes, optical disks, CD-ROMs (compact disk read-only memory), and magneto-optical disks, ROMs (read-only memory), RAMs (random access memory), EPROMs (erasable programmable read-only memory), EEPROMs (electrically-erasable programmable read-only memory), magnet or optical cards, flash memory, or other commonly known type computer-readable storage medium suitable for storing electronic instructions. Moreover, the present invention may also be downloaded as a program file containing a computer program product, wherein the program file may be transferred from a remote computer to a requesting computer.

Although the present invention has been described in language specific to structural features and/or methodological acts, it is to be understood that the invention defined in the appended claims is not necessarily limited to the specific features and embodiments described.

What is claimed is:

1. A plasma etching method comprising:
providing, in a plasma etch chamber, a substrate including an etched dielectric film disposed under an organic mask, wherein a fluorocarbon etch product is disposed on one or more of the plasma etch chamber, organic mask, and etched dielectric film; and
removing at least a portion of the organic mask selectively to the dielectric film by exposing the etched dielectric film and organic mask to a plasma of a first etchant gas including silicon tetrafluoride (SiF₄).

2. The method as in claim 1, the method comprising:
plasma etching the dielectric film with a second etchant gas including a fluorocarbon source gas to form a recess in the dielectric film based on the organic mask, the plasma etching forming the fluorocarbon etch product.

3. The method as in claim 1, wherein the etched dielectric film and organic mask is exposed to the plasma of the first etchant gas for a duration sufficient to remove at least a majority of the organic mask thickness remaining over the etched dielectric film.

4. The method of claim 1, wherein the first etchant gas further comprises at least one of: O₂, CO₂, CO, COS, SO₂, H₂O, N₂, N₂:H₂ or NH₃.

5. The method of claim 4, wherein exposing the etched dielectric film and organic mask to the plasma of the etchant gas comprises introducing the SiF₄ into the plasma etch chamber at a volumetric flow rate of up to 50% of the total volumetric flow of the first etchant gas.

6. The method of claim 4, wherein exposing the etched dielectric film and organic mask to a plasma of a second etchant gas comprises introducing CO₂, N₂ and SiF₄ into the plasma etch chamber, wherein the CO₂:SiF₄ volumetric flow rate ratio is between about 2:1 and 10:1.

7. The method of claim 2, wherein the first etchant gas is substantially free of the fluorocarbon source gas.

8. The method of claim 1, wherein the organic mask comprises a photo resist layer, wherein the etched dielectric film comprises silicon and oxygen, and wherein the recess comprises a via landed on an etch stop layer comprising a material other than silica.

9. The method as in claim 7, wherein the dielectric film etched comprises a material layer having a dielectric constant below about 3.0 and wherein the etch stop layer comprises silicon carbon nitride (SiCN).

10. A plasma etching method, comprising:
providing, in a plasma etch chamber, a substrate with a dielectric layer disposed under a first mask including a patterned photo resist layer;
plasma etching a first feature in the dielectric layer with a first etchant gas including a fluorocarbon species until a stop layer is exposed; and removing at least a portion of the patterned photo resist layer with a plasma of a second etchant gas including silicon tetrafluoride (SiF₄) and substantially free of the fluorocarbon species.

11. The method as in claim 10, further comprising:
receiving the substrate with the dielectric layer disposed under a second mask including a patterned photo resist layer aligned to the first feature and a non-patterned organic layer filling in the first feature;
plasma etching a second feature in the dielectric layer with a third etchant gas; and
removing the non-patterned organic layer from the first feature with a plasma of a fourth etchant gas including silicon tetrafluoride (SiF₄).

12. The method as in claim 10, wherein the first feature is a via with an etched profile bow defined by a CD delta between a top and a middle of the etched via depth, and wherein removing the first patterned photoresist layer with a plasma of a second etchant gas increases the profile bow introduced by the plasma etching of the first feature with the first etchant gas by less than 100%.

13. The method of claim 10, wherein the first feature is a via, wherein the dielectric layer comprises SiCOH, and wherein the stop layer comprises SiCN.

14. The method of claim 11, wherein the first feature is a via and the second feature is a trench having a larger CD than the via, wherein the dielectric layer comprises SiCOH, wherein the stop layer comprises SiCN, and wherein the non-patterned organic layer comprises an organic bottom anti-reflective coating (BARC).

15. The method of claim 11, further comprising removing the stop layer of the multi-film dielectric stack after removing the non-patterned organic layer from the feature.

16. A computer-readable storage medium having stored thereon a set of machine-executable instructions which, when executed by a data-processing system, cause a plasma etch system to perform the method of claim 1.

17. A computer-readable storage medium having stored thereon a set of machine-executable instructions which, when executed by a data-processing system, cause a plasma etch system to perform the method of claim 10.

18. An microelectronic device comprising:
a silicon-containing dielectric film over a substrate, wherein a top surface of the silicon-containing dielectric film is substantially unprotected by any organic mask; and
a via formed through the dielectric film, wherein the via has a sidewall surface substantially free of fluorocarbon polymer and covered with a passivation layer comprising silicon fluoride etch products.

19. The device as in claim 18, wherein the dielectric film comprises SiCOH and wherein via has an etched profile bow defined by a CD delta between a top and a middle of the etched via depth that is less than 5 nm.

20. The device as in claim 8, wherein the the silicon fluoride etch products comprise SiF₂ and SiF₃.
